(19) United States
(12) Patent Application Publication
(10) Pub. No.: US 2012/0225269 A1
(43) Pub. Date: Sep. 6, 2012

(54) RADIO WAVE ABSORBING COATING

(76) Inventor: Oleksandr Radievich Bedjukh, Kiev (UA)

(21) Appl. No.: 13/379,308

(22) PCT Filed: Jun. 16, 2010
(86) PCT No.: PCT/UA2010/000031

§ 371 Date: May 18, 2012

(30) Foreign Application Priority Data
Jun. 17, 2009 (UA) A200906307

(51) Int. Cl. H05K 9/00; B32B 7/02

(52) U.S. Cl. 428/213; 428/411.1

(57) ABSTRACT

Radio wave absorbing coating, comprising at least one dielectric layer and at least one layer of electroconductive material, deposited onto said dielectric layer and with thickness less than characteristic skin-depth for selected material over the certain predefined radiofrequency band. Said coating is suitable for application over the broad radiofrequency band.

### FIELD OF THE INVENTION

This invention relates to the composition and structure of radio wave absorbing coatings, which can be deposited onto components of radio-electronic devices (e.g. transmitters, receivers and transceivers of digital communication systems) and meant for reduction of adverse human and animal health effect of preferably microwave irradiation.

### BACKGROUND ART

Production of thin and light broadband radio wave absorbing coatings is often related with use of multilayer composite structures based on three types of diffraction gratings, namely: direct Fresnel's gratings, reciprocal Fresnel's gratings and Fraunhofer's gratings (See, for instant: http://www.ptechnology.ru/MainPart/Avia Space/Avia Space1.html).

Coatings having layered arrangement of such gratings, which have different properties, provide 30-fold decrease of reflectivity in the wavelength range up to 3.5 cm. Unfortunately, total thickness of such coatings often measures up to 3 mm and specific weight up to 2.5 kg/m².

Therefore, actual problem is reduction of thickness, specific weight and cost of radio wave absorbing coatings and provision of their high and controllable absorptive characteristics over broad frequency band.

Radio wave absorbing coatings are known also under trademarks CHO-Shield 576™ and CHO-Shield 579™ They protect electronic devices against electromagnetic interference or users against preferably internal microwave emission of such devices (see http://www.russianelectronics.ru/leader-r/news/2237/doc6611.phtml). Said coatings are made as electroconductive epoxide compounds containing fine-dispersed metal such as copper, tin or silver. Electrical resistance of both said compounds is less than 0.06 Ohm/m².

These coatings provide 60-80 dB device's shielding in the frequency range from 30 MHz up to 1 GHz. They are significantly thinner and cheaper as compared with aforesaid grating coatings, but can operate in lower (and relatively narrow) frequency band.

Radio wave absorbing coating closest in technical essence is known from International publication WO/2008/023764 dated 28 Feb. 2008. It includes:

supporting frame in the form of a grate made from suitable inorganic material, and

a placed onto said frame electroconductive material in the form of electrically isolated spots of average cross size about 5 mm and thickness no less than 0.1 mm.

Such coating is able to absorb radio-waves with wavelength at least 5 mm and frequency up to 40 GHz.

However, total thickness and specific weight of such coating leave much to be desired, and size of electrically isolated spots of electroconductive material restricts possibility to control coating's absorptive properties over broad radiofrequency band.

### SUMMARY OF THE INVENTION

Proposed invention is based on the problem to create—by changing composition and structure of parts—such thin radio wave absorbing coating that will be suitable for use in broad radiofrequency band.

This problem is solved in that a radio wave absorbing coating according to the Invention comprises of:

at least one dielectric layer, and

at least one electroconductive layer deposited onto said dielectric layer and having thickness less than characteristic skin-depth for selected electroconductive material within pre-determined radiofrequency band.

The dielectric layer electrically isolates the electroconductive layer from the surface that must be coated. The electroconductive layer provides partial absorption and partial reflection of incident electromagnetic irradiation, if its thickness is less than characteristic skin-depth. Accordingly, selection of appropriate thickness of electroconductive layer can provide at least 50% power absorption of normally incident electromagnetic irradiation in broad frequency band of radio-waves.

First additional feature consists in that the radio wave absorbing coating further comprises of several pairs of said layers being alternated, herewith first dielectric layer is closely adjacent to the protected device surface, and each electroconductive layer has thickness less than characteristic skin-depth for selected electroconductive material within pre-determined radiofrequency band.

Use two or more pairs of layers, each of which comprises of the dielectric layer and the electroconductive layer, allows reflectivity variation. In fact, setting the number of pairs of said layers and composition and/or thickness and/or electroconductivity of different electroconductive layers assuming the thickness of each layer being less than characteristic skin-depth for selected material over the given radiofrequency band, makes it possible to increase significantly overall absorption and, hence, significantly reducing total reflectivity of radio wave absorbing coating.

Second additional feature consists in that the electroconductive layers gradually decrease in thickness with distance apart of the protected device surface, which the coating is deposited on. In fact, reflection from the electroconductive layer decreases if its thickness scales down. Respectively, it is possible further decrease reflectivity of such radio wave absorbing coating.

Third additional feature consists in that conductivity of the electroconductive layers gradually decrease with distance apart of the protected device surface, which the coating is deposited on. In fact, reflection from the electroconductive layer reduces if its conductivity decreases. Respectively, it is possible further decrease the reflectivity of such radio wave absorbing coating.

Fourth additional feature consists in that at least one nearest to the protected device surface electroconductive layer is made as an electrically closed circuit (i.e. either an entire layer or a layer composed of electrically connected islands). This allows absorbing at least 50% of incident radio-waves power in one electroconductive layer.

Fifth additional feature consists in that at least one nearest to the protected device surface electroconductive layer is made in the form of electrically unconnected islands. Under normal incidence of electromagnetic wave such island layers are almost similar to dielectric materials in reflectivity, but maintain active ability to absorb radio-waves. Herewith their reflectivity is almost constant up to the wavelength similar to linear dimensions of these islands, which therefore significantly broaden the band of absorbed radiation wavelengths.

Sixth additional feature consists in that the radio wave absorbing coating has additional outer dielectric layer. This layer not only protects underlying electroconductive layer against airborne corrosion, but also improves reflectivity matching on the interface between the air and overall radio wave absorbing coating.

### BRIEF DESCRIPTION OF THE DRAWINGS

Further the Invention is explained by detailed description of structure and method for production of proposed coating (including the list of initial materials and test results) with references to attached drawings, where:

FIG. 1 shows a coating having single dielectric layer and single electroconductive layer;

FIG. 2 shows a coating having two pairs of basic layers, each of which comprises of a dielectric layer and an electroconductive layer, and an additional external protective dielectric layer;

FIG. 3 shows electroconductive layer composed of electrically unconnected islands deposited on a dielectric substrate (plan view).

### BEST EMBODIMENTS OF THE INVENTION

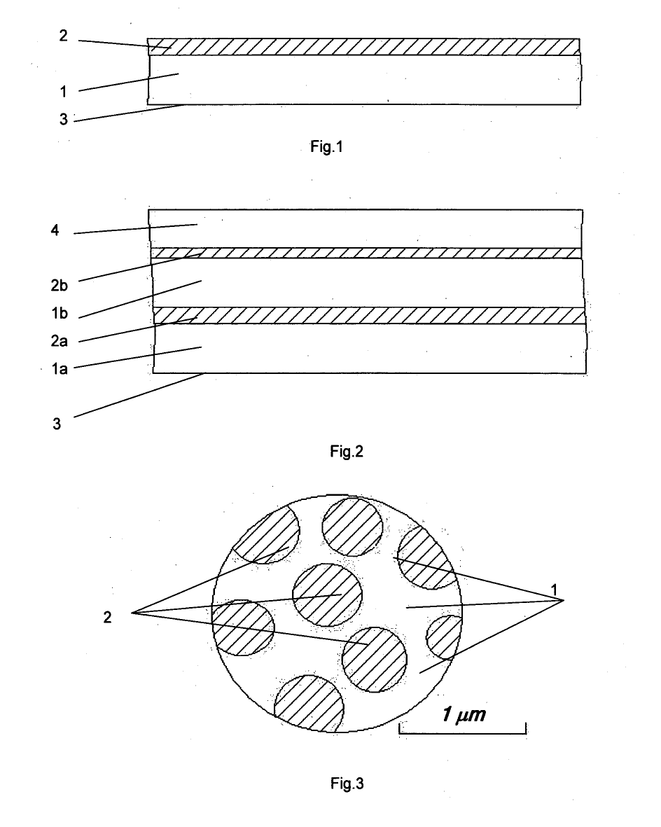

In general (see FIG. 1) radio wave absorbing coating comprises of at least one dielectric layer 1 and at least one electroconductive layer 2 deposited onto said dielectric layer 1 and being thinner as compared with the characteristic skin-depth for selected electroconductive material within the pre-determined frequency band. Dielectric layer 1 is closely adjacent to the surface 3 of protected device, if coating consists only of two said layers.

It is preferable if radio wave absorbing coating comprises of several pairs of said alternating layers, e.g. 1a and 2a, 1b and 2b etc. (see FIG. 2). In this case first dielectric layer 1a is closely adjacent to the protected device surface 3, and each electroconductive layer 2 (i.e. the layer 2a and the layer 2b) is thinner as compared with the characteristic skin-depth for selected electroconductive material within the pre-determined radiofrequency band.

In some embodiments of the Invention it is possible to gradually decrease thickness and/or conductivity of the electroconductive layers 2 (i.e. the layer 2a and the layer 2b on FIG. 2) with their distance from the protected device surface 3.

It is desirable if such multilayered radio wave absorbing coating has:

at least one nearest to the protected device surface 3 electroconductive layer 2, (particularly the layer 2a on FIG. 2), which is made as electrically closed circuit (i.e. either a some entire layer or a some layer composed of electrically connected islands), and

at least one most distanced from the protected device surface 3 electroconductive layer 2 (particularly the layer 2b on FIG. 2), which is made in the form of electrically unconnected islands.

In the last case (see FIG. 3) the average cross-size of said electroconductive islands created the layer 2 can be less than 1 μm and thickness less than 10 nm (as it is typical for magnetron deposition of gold or copper). This permits to absorb electromagnetic radiation up to 300 GHz frequency without substantial modifications.

Thus, even two-layered (and moreover, multilayered) radio wave absorbing coating could have additional external dielectric layer 4 shown, in particul, on FIG. 2.

Various dielectrics could be used as materials of the dielectric layer 1, e.g. pure carbon-chain polymers (in particular, polyethylene or polypropylene), electrical insulating ceramics etc.

The main requirement for selection of such materials is determined by deposition technology of theirs. Particularly they should be suitable for:

either for sputtering (like polyethylene and polypropylene powders),

or for smearing in thinnest possible layer (for example, like ceramic pastes),

or (mostly desirable) for direct deposition onto the contact surface using vacuum sputtering (like aluminum oxide, or silicon oxide etc.).

Minimal thickness of any dielectric layer 1 depends on profile and roughness of the coverable surface (namely, the protected device surface 3, or any previous electroconductive layer 2).

Electroconductive material could be:

a doped semiconductor (for example, doped germanium, silicon, etc.),

a metal alloy (for example, brass, bronze, etc.), but preferably

a pure metal (for example, copper, titanium, silver, gold, etc.).

Preferable method for deposition of proposed radio wave absorbing coating includes following main steps:

a) placing of a device, surface of which should be coated, into a vacuum chamber,

b) thermal vacuum or ion-plasma deposition of first dielectric layer 1,

c) also thermal vacuum or ion-plasma deposition of first electroconductive layer 2 having thickness less than characteristic skin-depth for selected material in pre-determined radiofrequency band,

d) replication of said steps (a) and (b), if multilayer coating needs to be formed,

e) deposition of additional dielectric layer 4, if this is specified, and

f) removing of the coated device from the vacuum chamber.

This method provides minimal total thickness of said coating in the range from 0.1 to 10 μm and minimal consumption of necessary materials.

In order to check invention practicability, several experiments were performed for measure of radio-wave absorption properties of sample coating comprising:

at least one dielectric layer 1 of low-density polyethylene having relative dielectric permittivity 2.3-2.4, dielectric loss tangent less than 10⁻³ and thickness less than 1 mm, and

at least one electroconductive layer 2 of electrical copper (with purity higher than 99%) and thickness in the range from 5 to 15 nm.

Copper layer was deposited using ion-plasma (magnetron) sputtering by experimental equipment based on russian industrial vacuum cart BYII-5 (http://iontecs.ru/index.php?id=70).

Electroconductive layer 2 having thickness 10-15 nm may be made as aforesaid electrically closed circuit. If electroconductive layer 2 has thickness less than 10 nm (preferably less than 8 nm but desirably no less than 5 nm) it takes a form of electrically unconnected islands, as it shown on FIG. 3.

Herewith skin-depth of a copper layer for the 38 GHz radiation frequency is about 1 μm that significantly exceeds thickness of each deposited copper sample layers 2.

Closure of circuits of electroconductive layers was tested by direct measurements of their surface resistance using Russian voltmeter B7-38 (htto://www.iais.ru/v7-38.html). Copper layers samples of 10 nm thickness and more had high surface electric conductivity, but samples with thickness less than 10 nm not had conductivity.

Radio wave absorbtion properties of the samples were tested as follows.

Samples were placed inside the 8-mm short-circuited waveguide section (dimensions 7.2*3.4 mm²) normally to its geometric axis, completely spanning the channel. Reflecting and absorbing properties of the coatings were measured when dielectric surface of samples was tightly contacted to the metal surface of short-circuited end with waveguide connected to the panoramic analyzer of VSWR (voltage standing-wave ratio) P2-65 (http://www.mprofit.ru/item376.htm).

VSWR measurements within the radiofrequency band 25.2-37.5 GHz provided following results:

VSWR values for the copper layer having form of electrically isolated islands and thickness from 5 nm up to about 8 nm are varied from 30 to 18, being approximately equal over the overall specified radiofrequency band. Such VSWR values correspond to the power reflection ratio from the samples surface in the range from 90% (for VSWR=30) to 80% (for VSWR=18).

VSWR values for the electrically closed copper layer having thickness from 10 nm up to 15 nm are varied from 4 up to 6, being approximately equal over the overall specified radiofrequency band. Such VSWR values scaled to the reflection ratio correspond to the radio-waves reflecting from the samples surface from 35% (for VSWR=4) and up to 50% (for VSWR=6).

Samples with electroconductive layer 2 in the form of electrically isolated copper islands were also tested using waveguide section with matched load. In such cases VSWR was less than 2 over the overall radiofrequency band, which approximately corresponds to reflection from the sample of pure dielectric material (low-density polyethylene).

In one experiment two samples were simultaneously placed into the waveguide section, each of them was previously investigated using above-mentioned equipment. First sample had electrically closed circuit copper layer with thickness at least 10 nm and VSWR varied in the range 3-4 over the whole specified radiofrequency band, which corresponds to at least 35% power reflection. Second sample had copper layer in the form of isolated islands with thickness about 8 nm and VSWR about 18, which corresponds to 80% power reflection.

Two said samples were placed according to the multilayer coating arrangement which is shown on FIG. 2 (except of the outer dielectric layer 4).

In this case electroconductive copper layer 2a, closest to the metal surface 3 of short-circuited waveguide end, was electrically closed, but second electroconductive layer 2b, apart of this surface 3 had the form of electrically isolated islands. VSWR measurements of reflectance properties of such multilayer sample provided values from 1.3 to 2.2 over the whole specified frequency band, which correspond to about 10% power reflection and hence about 90% power absorbance.

### Industrial Applicability

Coating according to this Invention could be easily made on the enterprises equipped with vacuum facilities for thermal vacuum or ion-plasma deposition of coatings. Proposed coating type while being much thinner compared to known radio wave absorbing coatings, provides significant absorbing effect of the incident electromagnetic radiation of higher frequencies.

1. A radio wave absorbing coating comprising at least one dielectric layer, and at least one electroconductive layer deposited onto said dielectric layer and having thickness less than characteristic skin-depth for selected electroconductive material within pre-determined radiofrequency band.

2. The radio wave absorbing coating according to the claim 1 that further comprises of several pairs of said layers being alternated, herewith first dielectric layer is closely adjacent to the protected device surface, and each electroconductive layer has thickness less than characteristic skin-depth for selected electroconductive material within pre-determined radiofrequency band.

3. The radio wave absorbing coating according to the claim 2, wherein the electroconductive layers gradually decrease in thickness with distance apart of the protected device surface, which the coating is deposited on.

4. The radio wave absorbing coating according to the claim 2, wherein conductivity of the electroconductive layers gradually decrease with distance apart of the protected device surface, which the coating is deposited on.

5. The radio wave absorbing coating according to the claim 2, wherein at least one nearest to the protected device surface electroconductive layer is made as an electrically closed circuit.

6. The radio wave absorbing coating according to the claim 2, wherein at least one nearest to the protected device surface electroconductive layer is made in the form of electrically unconnected islands.

7. The radio wave absorbing coating according to the claim 1 that has additional outer dielectric layer.

8. The radio wave absorbing coating according to the claim 2 that has additional outer dielectric layer.
